(19) United States
(12) Patent Application Publication
(10) Pub. No.: US 2025/0349518 A1
(43) Pub. Date: Nov. 13, 2025

(54) PLASMA CHAMBER HAVING SIDE GAS FEED FOR FORMING SWIRL MOTION

(71) Applicant: NYSE Star Corp., County of New Castle, DE (US)

(72) Inventors: Nam Hun KIM, Yeoju-si, Gyeonggi-do (KR); Woo Il CHO, Osan-si, Gyeonggi-do (KR)

(73) Assignee: NYSE Star Corp., County of New Castle, DE (US)

(21) Appl. No.: 18/871,479

(22) PCT Filed: May 22, 2023
(86) PCT No.: PCT/KR2023/006886

§ 371 Date: Dec. 4, 2024

(30) Foreign Application Priority Data
Jun. 9, 2022 (KR) 10-2022-0070200

(51) Int. Cl. H01J 37/32

(52) U.S. Cl. CPC H01J 37/3244; H01J 2237/334

(57) ABSTRACT

The present invention relates to a plasma chamber having a side gas feed for forming a swirl motion, the plasma chamber comprising: a housing having a seating portion on which a wafer is seated; and a side gas feed formed on a lateral surface of the housing so as to eject a gas into the housing, wherein the housing has a plurality of the side gas feeds and each side gas feed comprises a nozzle through which a gas is ejected, thereby ejecting a gas toward a wall surface of the housing.

### TECHNICAL FIELD

The present invention relates to a plasma chamber having a side gas feed for forming a swirl motion, and more specifically, to a plasma chamber having a side gas feed for forming a swirl motion, in which gas sprayed from a nozzle forms a swirl motion in the chamber by adjusting a spraying direction of the gas sprayed from a side gas feed toward a wall surface of a housing, thereby maintaining a uniform etch rate in the chamber.

### BACKGROUND ART

In general, it is very important to secure uniformity during a process of manufacturing a semiconductor, and the uniformity of semiconductors can be secured or controlled in an etching process among processes of manufacturing a semiconductor.

An etching process of the semiconductor can be performed in a plasma chamber. Plasma is generated in an internal reaction space of the plasma chamber, and the etching process of the semiconductor is performed using the plasma.

A plasma source for generating plasma is provided in an upper portion of the plasma chamber, and a representative example of the plasma source includes a capacitively coupled plasma (CCP) source, an inductively coupled plasma (ICP) source, and the like.

In an etching process, the distribution of gas inside the plasma chamber can be an important factor for maintaining a uniform etch rate. In general, to maintain the uniform etch rate, a shower head design is used for chambers using a CCP source, and a bottom gas feed (BGF), a center gas feed (CGF), and a side gas feed (SGF) are for in chambers using ICP.

The ICP can increase an etch rate compared to the CCP, but the ICP has a problem of low selectivity and poor process repeatability.

In addition, in order for the conventional ICP, main gas was injected from the center gas feed, and a small amount of gas was injected through the side gas feed to compensate a low etch rate at a wafer edge. Through such a method, the etch rate of the wafer edge can be controlled, thereby expecting the improvement of the uniformity of line widths.

However, since the orientation of a nozzle of the side gas feed for the conventional ICP faces the wafer, there is a problem that the etch rate is not uniform in the case of gases with large molecular weights.

Specifically, when the main gas is injected from the center gas feed and a small amount of gas is injected from the side gas feed, there is a problem that since the gas from the side gas feed leaks through a space between the chamber and the wafer, the effect of line width improvement cannot be obtained.

In contrast, when the amount of gas injected from the side gas feed is increased, there is a problem that the uniformity of the line widths in the entire wafer is affected, thereby obtaining a different result from a target result.

### DISCLOSURE

### Technical Problem

The present invention is intended to solve the above problems, and more specifically, to provide a plasma chamber having a side gas feed for forming a swirl motion, in which gas sprayed from a nozzle forms a swirl motion in the chamber by adjusting a spraying direction of the gas sprayed from a side gas feed toward a wall surface of a housing, thereby maintaining a uniform etch rate in the chamber.

### Technical Solution

A plasma chamber having a side gas feed for forming a swirl motion according to the present invention for solving the above problems, in which plasma is generated to etch a wafer, includes a housing having a seating part on which the wafer is seated, and a side gas feed provided on a side surface of the housing and sprays gas into the housing, wherein the side gas feed is provided as a plurality of side gas feeds on the housing, each of the side gas feeds includes a nozzle having a nozzle hole through which the gas is sprayed, and the side gas feed sprays the gas toward a wall surface of the housing.

In the plasma chamber having the side gas feed for forming a swirl motion according to the present invention for solving the above problems, the plurality of side gas feeds provided on the housing may be provided at the same height from the seating part.

In the plasma chamber having the side gas feed for forming a swirl motion according to the present invention for solving the above problems, a spraying direction of the gas from the side gas feed may be a planar direction extending in a direction parallel to a plane formed by the seating part on which the wafer is seated.

In the plasma chamber having the side gas feed for forming a swirl motion according to the present invention for solving the above problems, when any one of the plurality of side gas feeds provided on the housing is referred to as a first side gas feed and a side gas feed adjacent to the first side gas feed is referred to as a second side gas feed, the first side gas feed may spray the gas toward the second side gas feed.

In the plasma chamber having the side gas feed for forming a swirl motion according to the present invention for solving the above problems, when any one of the plurality of side gas feeds provided on the housing is referred to as a first side gas feed, a side gas feed adjacent to the first side gas feed is referred to as a second side gas feed, and a side gas feed adjacent to the second side gas feed in a direction opposite to a direction in which the first side gas feed is adjacent is referred to as a third side gas feed, the first side gas feed may spray the gas in a direction between the second side gas feed and the third side gas feed.

In the plasma chamber having the side gas feed for forming a swirl motion according to the present invention for solving the above problems, the number of the side gas feeds provided on the housing may be n (n is a natural number greater than or equal to 3, and n is the number of side gas feeds).

In the plasma chamber having the side gas feed for forming a swirl motion according to the present invention for solving the above problems, the plurality of side gas feeds provided on the housing may be provided on the housing in the shape of a regular polygon.

In the plasma chamber having the side gas feed for forming a swirl motion according to the present invention for solving the above problems, when the number of side gas feeds provided at the same height from the seating part is n, an angle formed by one side gas feed and two side gas feeds adjacent to both sides of the one side gas feed may be 180×(n−2)/n degrees.

The plasma chamber having the side gas feed for forming a swirl motion according to the present invention for solving the above problems may further include a center gas feed provided on an upper portion of the housing to spray gas into the housing.

In the plasma chamber having the side gas feed for forming a swirl motion according to the present invention for solving the above problems, the gas sprayed from the side gas feed may be gas having a heavier molecular weight than the gas sprayed from the center gas feed has.

In the plasma chamber having the side gas feed for forming a swirl motion according to the present invention for solving the above problems, the plasma generated in an internal space of the housing may include ions and radicals, and the wafer may be etched by a synergy effect of the ions and the radicals.

In the plasma chamber having the side gas feed for forming a swirl motion according to the present invention for solving the above problems, the nozzle hole may be formed in a circular shape having a diameter of 0.1 to 1 mm.

In the plasma chamber having the side gas feed for forming a swirl motion according to the present invention for solving the above problems, the side gas feed provided on the housing may be provided with a controller configured to adjust an amount or flow rate of the gas sprayed from the side gas feed.

### Advantageous Effects

The present invention relates to a plasma chamber having a side gas feed for forming a swirl motion, and gas sprayed from a nozzle forms a swirl motion in a chamber by adjusting a spraying direction of the gas sprayed from a side gas feed toward a wall surface of a housing, thereby maintaining a uniform etch rate in the chamber.

In addition, according to the present invention, the gas sprayed from the nozzle can form the swirl motion in the chamber by adjusting a spraying direction of gas from one side gas feed provided on the housing toward another side gas feed adjacent to the one side gas feed, thereby maintaining the uniform etch rate in the chamber.

In addition, according the present invention, since the spraying direction of the gas sprayed from the side gas feed can be adjusted toward a wall surface of the housing to form a flow rate or amount of the gas sprayed from one side gas feed so that the gas reaches another adjacent side gas feed, it is possible to prevent the gas sprayed from the side gas feed from hitting the wall surface of the housing.

In addition, according to the present invention, since the flow rate or amount of the gas sprayed from one side gas feed is formed so that the gas reaches another adjacent side gas feed, the gas sprayed from the one side gas feed can receive a force from another side gas feed to form a swirl motion.

In addition, according to the present invention, since the heavy molecular gas is sprayed through the side gas feed simultaneously using the side gas feed and a center gas feed in the chamber, it is possible to improve the uniformity of the etch rate and increase the etch rate.

### DESCRIPTION OF DRAWINGS

FIG. 1 is a view illustrating a plasma chamber according to an embodiment of the present invention.

FIG. 2 is a view illustrating a plasma chamber having a side gas feed and a center gas feed according to an embodiment of the present invention.

FIG. 3 is a view illustrating a plurality of side gas feeds installed in a housing according to an embodiment of the present invention.

FIG. 4 is a view illustrating an example in which a spraying direction of gas from a first side gas feed is a direction toward a second side gas feed according to the embodiment of the present invention.

FIG. 5 is a view illustrating an example in which a spraying direction of gas from the first side gas feed is directions toward the second side gas feed and a third side gas feed according to an embodiment of the present invention.

FIG. 6 is a view illustrating angles between side gas feeds when six side gas feeds are provided on the housing according to an embodiment of the present invention.

FIG. 7 is a view illustrating angles between side gas feeds when four side gas feeds are provided on the housing according to an embodiment of the present invention.

FIG. 8 is a view illustrating angles between side gas feeds when eight side gas feeds are provided on the housing according to an embodiment of the present invention.

### MODES OF THE INVENTION

The present specification clarifies the scope of the present invention, describes the principles of the present invention, and discloses embodiments so that those skilled in the art to which the present invention pertains can practice the present invention. Disclosed embodiments may be implemented in any of various forms.

The expressions “include” or “may include” that can be used in various embodiments of the present invention indicate the presence of the disclosed corresponding function, operation, component, or the like and do not limit one or more additional functions, operations, components, or the like. In addition, in various embodiments of the present invention, it should be understood that terms “include” and “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof.

When a certain component is described as being “connected” or “coupled” to another component, it should be understood that the certain component may be directly connected or coupled to the other component, but a new component may be present between the certain component and the other component. On the other hand, when a certain component is described as being “directly connected” or “directly coupled” to another component, it should be understood that no new component is present between the certain component and the other component.

The terms first, second, etc. used herein may be used to describe various components, but the components should not be limited by the terms. The terms are used only for the purpose of distinguishing one component from another component.

The present invention relates to a plasma chamber having a side gas feed for forming a swirl motion and to a plasma chamber having a side gas feed for forming a swirl motion, in which gas sprayed from a nozzle forms a swirl motion in the chamber by adjusting a spraying direction of the gas sprayed from a side gas feed toward a wall surface of a housing, thereby maintaining a uniform etch rate in the chamber.

The plasma chamber having the side gas feed for forming a swirl motion according to the embodiment of the present invention can improve the uniformity of an etch rate in a chamber using heavy molecules, in which metal etching or oxide etching is performed.

However, the present invention is not limited thereto, and it is apparent that the plasma chamber having the side gas feed for forming a swirl motion according to the embodiment of the present invention may be applied to a chamber using various molecules. Hereinafter, exemplary embodiments of the present invention will be described in detail with reference to the accompanying drawings.

A plasma chamber having a side gas feed for forming a swirl motion according to the embodiment of the present invention includes a housing 110 and a side gas feed 120.

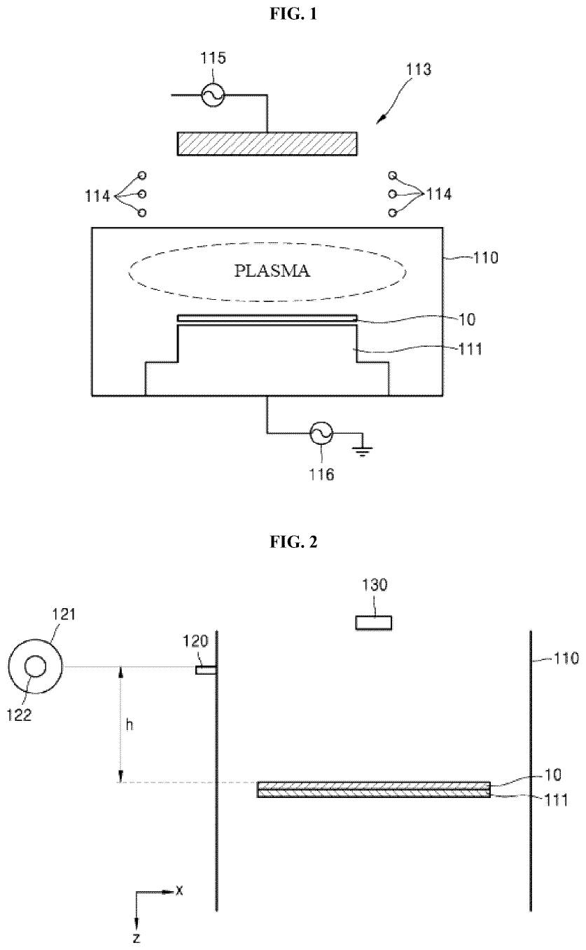

Referring to FIG. 1, the housing 110 has a reaction space provided therein to etch a wafer 10 through plasma. The housing 110 may be an outer wall of the plasma chamber according to the embodiment of the present invention and have a space provided therein.

The housing 110 may have a seating part 111 on which the wafer 10 is seated, and the wafer 10 may be loaded onto the seating part 111. When the wafer 10 is loaded into the housing 110, the wafer 10 may be etched by plasma formed inside the housing 110.

The seating part 111 may be a plate which is provided inside the housing 110 and on which the wafer 10 is seated, and the seating part 111 may be a wafer chuck for seating and supporting the wafer 10.

According to the embodiment of the present invention, a plasma source 113 for generating plasma may be provided above the housing 110. Referring to FIG. 1, the plasma source 113 may include coils 114 and a radio frequency (RF) power generator 115 and generate plasma in the housing 110 through the coils 114 and the RF power generator 115.

The plasma chamber having the side gas feed according to the embodiment of the present invention may further include a bias RF source 116 for applying a bias to the seating part 111. Referring to FIG. 1, the bias RF source 116 may apply a bias to the plasma during an etching process by applying a bias to the seating part 111.

The plasma chamber having the side gas feed for forming a swirl motion according to the embodiment of the present invention can solve and improve the problems of the conventional method using an inductively coupled plasma (ICP) source.

In addition, the plasma chamber having the side gas feed according to the embodiment of the present invention may use synergistic resonance ICP (SRICP) using a resonance and a synergy effect.

Specifically, the plasma generated in an internal space of the housing 110 of the plasma chamber having the side gas feed according to the embodiment of the present invention includes ions and radicals, and the wafer 10 may be etched by the synergy effect of the ions and the radicals.

The plasma is generally composed of electrons, ions, and radicals. Describing the conventional method of etching a wafer using plasma, the dominant species in the plasma etching process is formed as either ions or radicals. Specifically, in the conventional method of etching a wafer using plasma, metal etching is performed mainly using radicals, and oxide etching is performed mainly using ions.

In the plasma chamber having the side gas feed according to the embodiment of the present invention, the plasma etching process may use dominant species formed by simultaneously using ions and radicals rather than either ions or radicals.

That is, in the plasma chamber having the side gas feed according to the embodiment of the present invention, a process region in which ions and radicals act together to exhibit the synergy effect rather than an ion-dominated reaction or a radical-dominated reaction is used during the etching process.

More specifically, in the plasma chamber having the side gas feed according to the embodiment of the present invention, a high etch rate can be maintained and improve selectivity through the resonance and the synergy effect between ions and radicals by simultaneously using the ions and the radicals.

Referring to FIG. 2, the side gas feed 120 is provided on a side surface of the housing 110 and injects gas into the housing 110. The housing 110 may have a plurality of side gas feeds 120.

The side gas feed 120 may include a nozzle 121 having a nozzle hole 122 through which gas is sprayed, and a plurality of nozzles 121 may be provided in the housing 110.

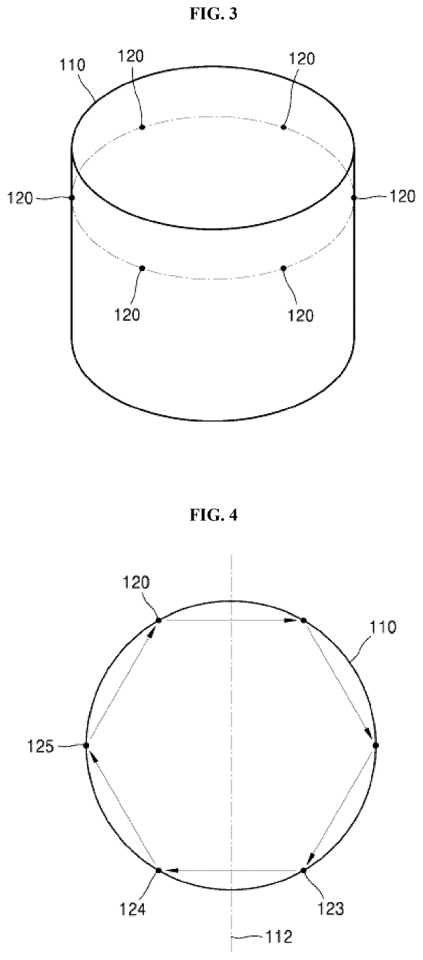

Referring to FIG. 3, the plurality of side gas feeds 120 provided on the housing 110 may be provided at the same height from the seating part 111. In addition, a spraying direction of the gas from the plurality of side gas feeds 120 provided on the housing 110 may be a planar direction extending in a direction parallel to a plane formed by the seating part 111 on which the wafer 10 is seated.

The plurality of side gas feeds 120 may spray gas along a single plane, and the plurality of side gas feeds 120 may be provided to be coplanar at the same height from the seating part 111.

Specifically, the plurality of side gas feeds 120 may be spaced a predetermined height h from the seating part 111 and disposed on the plane extending in the direction parallel to the plane formed by the seating part 111.

In addition, the plurality of side gas feeds 120 may be spaced the predetermined height h from the seating part 111 and may spray gas toward the wall surface of the housing 110 along a plane extending in the direction parallel to the plane formed by the seating part 111.

Referring to FIGS. 3 and 4, the plurality of side gas feeds 120 provided on the housing 110 may form a regular polygonal shape and may be provided on the housing 110. Specifically, the plurality of side gas feeds 120 may form a regular polygon on the plane extending in the direction parallel to the plane formed by the seating part 111 and may be provided on the housing 110.

Referring to FIGS. 3 and 4, the side gas feed 120 may spray gas toward the wall surface of the housing 110. The nozzle hole 122 of the side gas feed 120 may be disposed to face the wall surface of the housing 110, and the plurality of side gas feeds 120 may spray gas at a predetermined angle with respect to the wall surface of the housing 110.

Specifically, referring to FIG. 4, a cross section of the housing 110 may be formed in a circular shape. When a tangent is formed at a point at which the housing 110 formed in a circular shape is in contact with the side gas feed 120, an angle formed between the tangent and the direction in which gas is sprayed from the side gas feed 120 may be formed as a predetermined angle.

According to the embodiment of the present invention, the spraying direction of gas from one side gas feed 120 provided on the housing 110 may be a direction toward another side gas feed 120 adjacent to the one side gas feed 120.

Referring to FIG. 4, when one of the plurality of side gas feeds 120 provided on the housing 110 is referred to as a first side gas feed 123 and the side gas feed 120 adjacent to the first side gas feed 123 is referred to as a second side gas feed 124, the first side gas feed 123 may spray gas toward the second side gas feed 124.

That is, the gas sprayed from the first side gas feed 123 may be sprayed to reach the second side gas feed 124. In this way, when the gas sprayed from the first side gas feed 123 is sprayed toward the second side gas feed 124, the gas sprayed from the first side gas feed 123 may receive a force from the second side gas feed 124 before hitting the wall surface of the housing 110.

As the gas sprayed from the first side gas feed 123 receives the force from the second side gas feed 124, the gas sprayed from the first side gas feed 123 may be rotated by the second side gas feed 124 instead of hitting the wall surface of the housing 110.

The gas sprayed from the first side gas feed 123 may be affected by gravity, and as the gas sprayed from the first side gas feed 123 rotates and moves downward in the direction of gravity to form a downward swirl motion.

When the gas sprayed from the first side gas feed 123 forms the downward swirl motion and is in contact with the wafer 10, the gas is additionally moved by a centrifugal force even when being in contact with the wafer 10, thereby causing the diffusion effect.

As the gas reacts with surrounding particles due to such a diffusion effect, the uniformity of the etch rate can be improved.

Referring to FIG. 4, when the side gas feed 120 adjacent to the second side gas feed 124 in a direction opposite to a direction in which the first side gas feed 123 is adjacent is referred to as the third side gas feed 125, the second side gas feed 124 may spray gas toward the third side gas feed 125. In addition, the third side gas feed 125 may spray gas to a fourth side gas feed provided in a direction opposite to the direction in which the second side gas feed 124 is adjacent.

In this way, since the plurality of side gas feeds 120 provided on the housing 110 may spray gas toward the adjacent side gas feed 120, the gas sprayed from the side gas feed 120 forms a downward swirl motion.

According to the embodiment of the present invention, the side gas feed 120 provided on the housing 110 may have a controller for controlling the flow rate or amount of the gas sprayed from the side gas feed 120.

As described above, the gas sprayed from one side gas feed 120 provided on the housing 110 forms a downward swirl motion by receiving a force from another side gas feed 120 only when moving to another adjacent side gas feed 120.

When the gas sprayed from the one side gas feed 120 does not reach another side gas feed 120, it is difficult to form a downward swirl motion.

Accordingly, the gas sprayed from the one side gas feed 120 needs to be sprayed with an amount or at a flow rate at which the gas may move to another adjacent side gas feed 120. The controller may adjust the flow rate or amount of the gas sprayed from the side gas feed 120, and the flow rate or amount of the gas may be adjusted through the controller so that the gas sprayed from the one side gas feed 120 may move to another adjacent side gas feed 120.

In addition, according to the embodiment of the present invention, a cross-sectional area A of the nozzle hole 122 formed on the one side gas feed 120 may be adjusted together with the flow rate or amount of the gas sprayed from the one side gas feed 120 so that the gas sprayed from the one side gas feed 120 moves to another adjacent side gas feed 120.

According to another embodiment of the present invention, the first side gas feed 123 may spray the gas in a direction between the second side gas feed 124 and the third side gas feed 125.

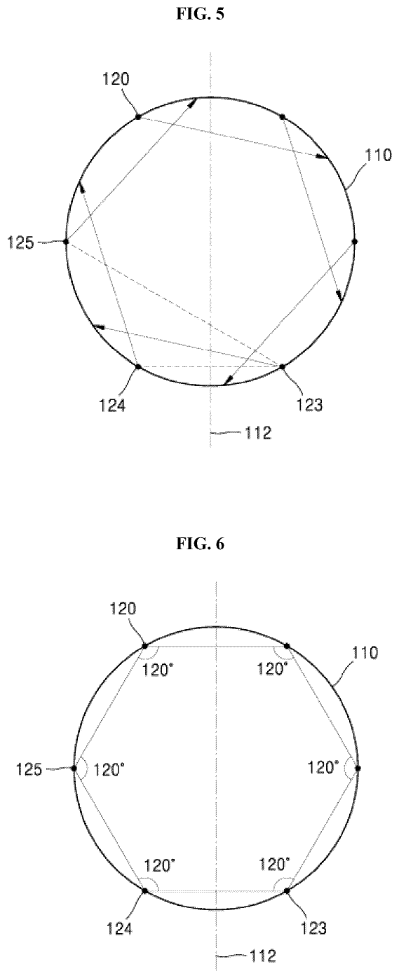

When one of the plurality of side gas feeds 120 provided on the housing 110 is referred to as the first side gas feed 123, the side gas feed 120 adjacent to the first side gas feed 123 is referred to as the second side gas feed 124, and the side gas feed 120 adjacent to the second side gas feed 124 in the direction opposite to the direction in which the second first side gas feed is adjacent is referred to as the third side gas feed 125, as illustrated in FIG. 5, the first side gas feed 123 may spray the gas in the direction between the second side gas feed 124 and the third side gas feed 125.

The gas sprayed from the first side gas feed 123 may receive a force from the second side gas feed 124 even when sprayed in a direction slightly misaligned with the direction toward the second side gas feed 124.

However, when the gas sprayed from the first side gas feed 123 is significantly misaligned with the direction toward the second side gas feed 124, the gas sprayed from the first side gas feed 123 may not receive the force from the second side gas feed 124.

Accordingly, the gas sprayed from the first side gas feed 123 is preferably sprayed in the direction between the second side gas feed 124 and the third side gas feed 125. In addition, the gas sprayed from the second side gas feed 124 may be sprayed in a direction between the third side gas feed 125 and the fourth side gas feed.

In such a method, since the plurality of side gas feeds 120 provided on the housing 110 may spray gas to the vicinity of the adjacent side gas feed 120, the gas sprayed from the side gas feed 120 forms a downward swirl motion.

Of course, even in this case, the flow rate or amount of the gas sprayed from the side gas feed 120 may be adjusted so that the gas sprayed from the first side gas feed 123 reaches the region between the second side gas feed 124 and the third side gas feed 125, and a cross-sectional area of the nozzle hole 122 may also be adjusted.

According to the embodiment of the present invention, n side gas feeds 120 may be provided on the housing 110. Here, n is a natural number greater than or equal to 3, and n may be the number of side gas feeds.

According to the embodiment of the present invention, three or more side gas feeds 120 are preferably provided. Specifically, the three or more side gas feeds 120 may be provided on the housing 110, and the three side gas feeds 120 may be disposed to be coplanar.

When the number of side gas feeds 120 is two, it is difficult to form a swirl motion, and thus three or more side gas feeds 120 are preferably provided.

More specifically, to form a swirl motion through the side gas feed 120, three to eight side gas feeds 120 are preferably provided on the housing 110.

However, the number of side gas feeds 120 provided on the housing 110 is not limited to 8, and the number of side gas feeds 120 provided on the housing 110 may be more than 8.

According to the embodiment of the present invention, the plurality of side gas feeds 120 may be provided on the housing 110 in the shape of a regular polygon. According to the embodiment of the present invention, when the number of side gas feeds 120 provided at the same height from the seating part 111 is n, an angle formed by one side gas feed and two side gas feeds adjacent to both sides of the one side gas feed may be 180×(n−2)/n degrees. (Here, since the number of side gas feeds 120 provided on the housing 110 is 3 or more, n in the expression of 180×(n−2)/n may be greater than 3.)

In the case in which the number of side gas feeds 120 provided at the same height from the seating part 111 is 6 as illustrated in FIG. 6, the angle formed by one side gas feed and two side gas feeds adjacent to both sides of the side gas feed may be 120 degrees.

In the case in which the number of side gas feeds 120 provided at the same height from the seating part 111 is 4 as illustrated in FIG. 7, the angle formed by one side gas feed and two side gas feeds adjacent to both sides of the one side gas feed may be 90 degrees.

Specifically, as illustrated in FIG. 6, when the number of side gas feeds 120 is 6, an angle formed by a line connecting the second side gas feed 124 to the first side gas feed 123 and a line connecting the second side gas feed 124 to the third side gas feed 125 may be 120 degrees.

In addition, as illustrated in FIG. 6, when the number of side gas feeds 120 is 4, the angle formed by the line connecting the second side gas feed 124 to the first side gas feed 123 and the line connecting the second side gas feed 124 to the third side gas feed 125 may be 90 degrees.

According to the embodiment of the present invention, when a tangent is formed at a point at which the housing 110 formed in a circular shape is in contact with the side gas feed 120, an angle formed by the tangent and the direction in which gas is sprayed from the side gas feed 120 may range from 20 to 60 degrees.

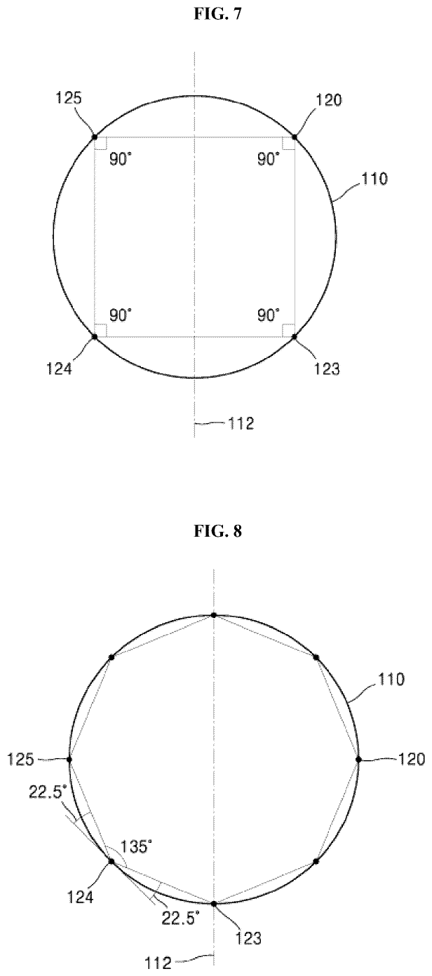

As described above, three to eight side gas feeds 120 are preferably provided on the housing 110. Referring to FIG. 8, when eight side gas feeds 120 are provided on the housing 110, the angle formed by the line connecting the second side gas feed 124 to the first side gas feed 123 and the line connecting the second side gas feed 124 to the third side gas feed 125 may be 135 degrees.

According to the embodiment of the present invention, the second side gas feed 124 may spray gas toward the third side gas feed 125. In this case, when a tangent is formed at a point at which the housing 110 formed in a circular shape is in contact with the second side gas feed 124, an angle formed by the tangent and a direction in which the gas is sprayed from the second side gas feed 124 may be 22.5 degrees.

In order for the gas sprayed from the second side gas feed 124 to receive a force from the third side gas feed 125, the angle formed between the tangent and the direction in which the gas is sprayed from the second side gas feed 124 is preferably greater than 22.5 degrees.

Since the number of side gas feeds 120 provided on the housing 110 is preferably 8 or less, when the tangent is formed at the point at which the housing 110 formed in a circular shape is in contact with the side gas feed 120, the angle formed by the tangent and the direction in which the gas is sprayed from the side gas feed 120 is preferably greater than 22.5 degrees and more preferably greater than 20 degrees.

In addition, when three side gas feeds 120 are provided on the housing 110, the angle formed by the line connecting the second side gas feed 124 to the first side gas feed 123 and the line connecting the second side gas feed 124 to the third side gas feed 125 may be 60 degrees.

In this case, when the tangent is formed at the point at which the housing 110 formed in a circular shape is in contact with the second side gas feed 124, the angle formed by the tangent and the direction in which the gas is sprayed from the second side gas feed 124 may be 60 degrees.

Since the number of side gas feeds 120 provided on the housing 110 is preferably 3 or more, when the tangent is formed at the point at which the housing 110 formed in a circular shape is in contact with the side gas feed 120, the angle formed by the tangent and the direction in which the gas is sprayed from the side gas feed 120 is preferably smaller than 60 degrees.

The plasma chamber having the side gas feed for forming a swirl motion according to the embodiment of the present invention may further include a center gas feed 130 provided on an upper portion of the housing 110 to spray gas into the housing 110.

When gas sprayed into the plasma chamber consists of heavy molecules, there is a problem that the uniformity of an etch rate worsens due to an increase in rate in a z-direction (toward a lower portion of the housing) caused by the heavy molecules when only the center gas feed is used.

The plasma chamber having the side gas feed according to the embodiment of the present invention can adjust the design of the side gas feed 120 using the side gas feed 120 together with the center gas feed 130, thereby preventing the uniformity of the etch rate from worsening.

When the center gas feed 130 and the side gas feed 120 are used simultaneously, the side gas feed 120 is preferably provided between the seating part 111 of the housing 110 and the center gas feed 130 provided on the upper portion of the housing 110.

According to the embodiment of the present invention, the plasma generated in the reaction space of the housing 110 includes ions and radicals, and the wafer 10 may be etched by the synergistic effect of the ions and the radicals.

According to the embodiment of the present invention, the plasma generated in the reaction space of the housing 110 includes electrons, and an electron energy relaxation length (EERL) of the electrons may be smaller than a diameter of the housing.

The plasma chamber having the side gas feed for forming a swirl motion according to the embodiment of the present invention may be performed in a process region of local electron kinetics. The conventional etching process is performed in a process region of nonlocal electron kinetics in which the EERL is always greater than the diameter of a process chamber.

However, the plasma chamber having the side gas feed for forming a swirl motion according to the embodiment of the present invention may be performed in a process region of local electron kinetics in which the EERL is smaller than the diameter of the process chamber (the diameter of the housing 110).

According to the plasma chamber having the side gas feed for forming a swirl motion according to the embodiment of the present invention, plasma at an edge of the housing 110 may have a higher density than the center of the housing 110, and an etch rate may be higher at the edge of the housing 110 than at the center of the housing 110.

In the conventional etching process, a problem that etching is performed not enough at the edge of the wafer (a low edge yield problem) may occur, and the plasma chamber having the side gas feed according to the embodiment of the present invention can prevent the occurrence of the problem by making a higher etch rate at the edge of the housing 110 than at the center of the housing 110.

In addition, in the conventional etching process, to solve the problem that etching is performed not enough at the edge of the wafer (the low edge yield problem), independent RF power is applied, or a heater, a lift device for preventing erosion of an edge ring due to plasma, or the like is used.

However, since the plasma chamber having the side gas feed for forming a swirl motion according to the embodiment of the present invention may not use a separate device because the etch rate at the edge of the housing 110 is higher than the edge rate at the center of the housing 110, it is possible to reduce a manufacturing cost and expect yield improvement.

The plasma chamber having the side gas feed for forming a swirl motion according to the embodiment of the present invention may be performed in a process region of local electron kinetics so that the density of plasma inside the housing 110 may increase from the inside of the housing 110 to the outside of the housing 110.

Accordingly, it is possible to obtain a concave etch rate profile in which an etch rate is low at inner side in the housing 110 and the etch rate increases toward an outer side in the housing 110. It is possible to solve the low edge yield problem in which the etch rate decreases at the edge of the housing 110 through the concave etch rate profile.

However, when the gas of heavy molecules is sprayed only through the center gas feed 130, the concave etch rate profile cannot be obtained. That is, in a case in which the gas of heavy molecules is present, when the gas of heavy molecules is sprayed from the center gas feed 130, the process region of local electron kinetics may not be valid.

To solve such a problem, the plasma chamber having the side gas feed for forming a swirl motion according to the embodiment of the present invention may spray gas of heavy molecules from the side gas feed 120.

According to the embodiment of the present invention, the gas sprayed from the side gas feed 120 may have a heavier molecular weight than the gas sprayed from the center gas feed 130. Since the uniformity of an etch rate cannot be improved when the gas of the heavy molecules is sprayed from the center gas feed 130, the gas of the heavy molecules is preferably sprayed through the side gas feed 120.

Specifically, the gas of the heavy molecules may be sprayed from the side gas feed 120 to form a downward swirl motion, thereby improving the uniformity of an etch rate.

Here, the gas sprayed from the side gas feed 120 may have a heavier molecular weight than the gas sprayed from the center gas feed 130, but a part of the gas sprayed from the side gas feed 120 may not be heavier than the gas sprayed from the center gas feed 130 or may be the same as the gas sprayed from the center gas feed 130.

That is, the gas of heavy molecules may be sprayed only through the side gas feed 120, and general gas rather than the gas of heavy molecules may be sprayed from both the side gas feed 120 and the center gas feed 130.

According to the embodiment of the present invention, the side gas feed 120 includes the nozzle 121 having the nozzle hole 122 through which gas is sprayed, and a plurality of side gas feeds 120 may be provided on the housing 110.

According to the embodiment of the present invention, plasma density distribution may be affected by adjusting a radius of the swirl motion formed by the gas sprayed from the side gas feed 120 considering the gas sprayed from the center gas feed 130.

Specifically, the radius of the swirl motion formed by the gas sprayed from the side gas feed 120 may be adjusted to adjust the plasma density distribution of the concave etch rate profile.

As described above, the plasma chamber having the side gas feed for forming a swirl motion according to the embodiment of the present invention can obtain the concave etch rate profile in which an etch rate is low at an inner side in the housing 110 and the etch rate increases toward an outer side in the housing 110.

The concave etch rate profile can be obtained by adjusting an internal pressure of the housing 110. According to the embodiment of the present invention, in addition to the pressure-related factor, the radius of a swirl motion formed by the gas sprayed from the side gas feed 120 may be adjusted to adjust the plasma density distribution in the concave etch rate profile.

According to the embodiment of the present invention, the side gas feed 120 includes the nozzle 121 having the nozzle hole 122 through which gas is sprayed, and the plurality of side gas feeds 120 may be provided on the housing 110.

The plurality of side gas feeds 120 may be provided on upper, middle, and lower portions of the housing 110, and the plurality of side gas feeds 120 may be provided on one or more of the upper, middle, and lower portions of the housing 110.

According to the embodiment of the present invention, when the side gas feed 120 is provided on the lower portion of the housing 110, the uniformity of an etch rate can be improved, but when the side gas feed 120 is provided on the lower portion of the housing 110, the etch rate cannot be effectively improved. Accordingly, the plurality of side gas feeds 120 according to the embodiment of the present invention are preferably disposed at appropriate positions of the upper, middle, and lower portions of the housing 110.

Referring to FIG. 3, each nozzle 121 of the side gas feed 120 may have a plurality of nozzle holes 122. The sizes of the plurality of nozzle holes 122 provided in the nozzle 121 may be the same or different.

According to the embodiment of the present invention, the nozzle hole 122 is preferably formed in a circular shape having a diameter of 0.1 to 1 mm. Since arcking phenomenon may occur when the diameter of the nozzle hole 122 is greater than 1 mm, the diameter of the nozzle hole 122 is preferably smaller than 1 mm to prevent the arcking phenomenon. In addition, to efficiently spray gas through the nozzle hole 122, the diameter of the nozzle hole 122 is preferably greater than 0.1 mm.

According to the embodiment of the present invention, gas sprayed from the side gas feed 120 may form a downward swirl motion in the housing 110 and may be sprayed onto the wafer 10. In this case, the gas sprayed from the side gas feed 120 may form the downward swirl motion while rotating clockwise or counterclockwise.

The plasma chamber having the side gas feed according to the embodiment of the present invention uses the side gas feed 120 using ICP, and the gas sprayed from the side gas feed 120 may form a downward swirl motion.

The plasma chamber having the side gas feed according to the embodiment of the present invention in which gas sprayed from the side gas feed 120 forms a downward swirl motion can improve an etch rate by being applied to metal etching, oxide etching, and poly etching.

In addition, the side gas feed 120 that sprays gas to form a downward swirl motion may be applied to plasma processes such as plasma deposition, PR stripping, plasma dopping, etc.

The above plasma chamber having the side gas feed that forms a swirl motion according to the embodiment of the present invention has the following effects.

In the above-described plasma chamber having the side gas feed for forming a swirl motion according to the embodiment of the present invention, gas sprayed from the nozzle can form a swirl motion in the chamber by adjusting a spraying direction of the gas sprayed from the side gas feed toward the wall surface of the housing, thereby maintaining a uniform etch rate in the chamber.

In addition, in the plasma chamber having the side gas feed for forming a swirl motion according to the embodiment of the present invention, gas sprayed from the nozzle can form a swirl motion in the chamber by adjusting a spraying direction of gas from one side gas feed provided on the housing toward another side gas feed adjacent to the one side gas feed, thereby maintaining a uniform etch rate in the chamber.

In addition, in the plasma chamber having the side gas feed for forming a swirl motion according to the embodiment of the present invention, since a spraying direction of gas sprayed from the side gas feed can be adjusted toward a wall surface of the housing to form a flow rate or amount of the gas sprayed from one side gas feed so that the gas reaches another adjacent side gas feed, it is possible to prevent the gas sprayed from the side gas feed from hitting the wall surface of the housing.

In addition, in the plasma chamber having the side gas feed for forming a swirl motion according to the embodiment of the present invention, since a flow rate or amount of gas sprayed from one side gas feed is formed so that the gas reaches another adjacent side gas feed, the gas sprayed from the one side gas feed can receive a force from to form a swirl motion.

In addition, in the plasma chamber having the side gas feed for forming a swirl motion according to the embodiment of the present invention, since a heavy molecular gas is sprayed through the side gas feed simultaneously using the side gas feed and the center gas feed in the chamber, it is possible to improve the uniformity of an etch rate and increase the etch rate.

The plasma chamber having the side gas feed for forming a swirl motion according to the embodiment of the present invention can obtain an effect similar to that of using a confinement ring or an electromagnet because it forms a swirl motion. The process using the confinement ring can expect the enhancement of the density of plasma and an etch rate at the edge by directly controlling a space in which the process is performed.

In a process using an electromagnet, the electromagnet is disposed near a chamber, and since the electromagnet is disposed near the chamber, it is possible to control electrons to not leak to the wall surface of the housing.

The plasma chamber having the side gas feed for forming a swirl motion according to the embodiment of the present invention can obtain an effect similar to that of using a confinement ring or an electromagnet because it forms a swirl motion.

In addition, the plasma chamber having the side gas feed for forming a swirl motion according to the embodiment of the present invention can effectively improve the uniformity of an etch rate when performing metal etching or oxide etching and can contribute to the densities of radicals and ions by increasing the number of side gas feeds.

The present invention has been described above with reference to embodiments illustrated in the accompanying drawings, but this is merely illustrative, and those skilled in the art will understand that various modifications and substitutions of embodiments are possible therefrom. Therefore, the true technical scope of the present invention should be determined by the technical spirit of the appended claims.

1. A plasma chamber having a side gas feed for forming a swirl motion, in which plasma is generated to etch a wafer, the plasma chamber comprising:
a housing having a seating part on which the wafer is seated; and
a side gas feed that is provided on a side surface of the housing and sprays gas into the housing,
wherein the side gas feed is provided as a plurality of side gas feeds on the housing,
each of the side gas feeds includes a nozzle having a nozzle hole through which the gas is sprayed, and
the side gas feed sprays the gas toward a wall surface of the housing.

2. The plasma chamber of claim 1, wherein the plurality of side gas feeds provided on the housing are provided at the same height from the seating part.

3. The plasma chamber of claim 2, wherein a spraying direction of the gas from the side gas feed is a planar direction extending in a direction parallel to a plane formed by the seating part on which the wafer is seated.

4. The plasma chamber of claim 2, wherein, when any one of the plurality of side gas feeds provided on the housing is referred to as a first side gas feed and a side gas feed adjacent to the first side gas feed is referred to as a second side gas feed, the first side gas feed sprays the gas toward the second side gas feed.

5. The plasma chamber of claim 2, wherein, when any one of the plurality of side gas feeds provided on the housing is referred to as a first side gas feed, a side gas feed adjacent to the first side gas feed is referred to as a second side gas feed, and a side gas feed adjacent to the second side gas feed in a direction opposite to a direction in which the first side gas feed is adjacent is referred to as a third side gas feed, the first side gas feed sprays the gas in a direction between the second side gas feed and the third side gas feed.

6. The plasma chamber of claim 2, wherein the number of the side gas feeds provided on the housing is n (n is a natural number greater than or equal to 3, and n is the number of side gas feeds).

7. The plasma chamber of claim 2, wherein the plurality of side gas feeds provided on the housing are provided on the housing in the shape of a regular polygon.

8. The plasma chamber of claim 2, wherein when the number of side gas feeds provided at the same height from the seating part is n, an angle formed by one side gas feed and two side gas feeds adjacent to both sides of the one side gas feed is 180×(n−2)/n degrees.

9. The plasma chamber of claim 1, further comprising a center gas feed provided on an upper portion of the housing to spray gas into the housing.

10. The plasma chamber of claim 9, wherein the gas sprayed from the side gas feed is gas having a heavier molecular weight than the gas sprayed from the center gas feed.

11. The plasma chamber of claim 1, wherein the plasma generated in an internal space of the housing includes ions and radicals, and the wafer is etched by a synergy effect of the ions and the radicals.

12. The plasma chamber of claim 1, wherein the nozzle hole is formed in a circular shape having a diameter of 0.1 to 1 mm.

13. The plasma chamber of claim 1, wherein the side gas feed provided on the housing is provided with a controller configured to adjust an amount or flow rate of the gas sprayed from the side gas feed.
